(19) United States
(12) Patent Application Publication
(10) Pub. No.: US 2016/0020351 A1
(43) Pub. Date: Jan. 21, 2016

(54) BIFACIAL-CELL-BASED SOLAR-ENERGY CONVERTING SYSTEM

(71) Applicant: Prism Solar Technologies Incorporated, Highland, NY (US)

(72) Inventors: Jose E. Castillo-Aguilella, Tucson, AZ (US); Paul S. Hauser, Tucson, AZ (US); Jerome E. Hughes, Golden, CO (US); Kevin R. Stewart, Niskayuna, NY (US)

(21) Appl. No.: 14/803,924

(22) Filed: Jul. 20, 2015

Related U.S. Application Data
(60) Provisional application No. 62/026,338, filed on Jul. 18, 2014.

(51) Int. Cl. H01L 31/068; H01L 31/048

(52) U.S. Cl. CPC H01L 31/0684; H01L 31/048; H01L 31/0488

(57) ABSTRACT

A method to optimize electrical energy production from a bifacial module (“BFM”) comprising a plurality of electrically interconnected bifacial photovoltaic cells is disclosed. Applicants' method includes providing a BFM, providing a reflector assembly, positioning the BFM at least about 0.15 meters above the reflector assembly, adjusting an orientation of the BFM using a Tilt Correction Factor, utilizing a minimum spacing between BFMs and further adjusting the orientation using an Azimuth Correction Factor.

### CROSS-REFERENCE TO RELATED APPLICATIONS

This Non-Provisional application claims priority to a U.S. Provisional Application filed Jul. 18, 2014, and having Ser. No. 62/026,338, which is hereby incorporated herein by reference.

### FIELD OF THE INVENTION

Disclosed herein is a bi-facial photovoltaic solar-energy converting system. In certain embodiments, that system includes an auxiliary reflector and method for conversion of solar energy structured to maximize the electrical output from such a bifacial-cell-based solar-energy converting system.

### BACKGROUND OF THE INVENTION

Bifacial-cell-based solar modules (interchangeably referred to hereinafter as bifacial modules, or BFMs) have been shown to produce more power than equally rated monofacial modules, due to the ability of bifacial cells (BFCs) to engage the back-side of the module to harvest sunlight incident on it and convert it to electrical energy.

Configuring an orientation of the BFM in a solar-energy converting system to optimize the electrical output therefrom requires optimization of the solar energy converting system, and should be done with respect to the elements of the ambient light sources which are an important contributor to the solution of this problem, that has been not provided by related art to-date. Embodiments of the present invention provide solutions to this and other questions by complementing a BFM with an auxiliary reflector with a judiciously chosen albedo and orientation with respect to the BFM such that energy production from the so-formed system is maximized.

### SUMMARY OF THE INVENTION

A method to optimize electrical energy production from a bifacial module (“BFM”) comprising a plurality of electrically interconnected bifacial photovoltaic cells is disclosed. Applicants' method includes providing a BFM, providing a reflector assembly, positioning the BFM at least about 0.15 meters above the reflector assembly, adjusting an orientation of the BFM using a Tilt Correction Factor, and further adjusting the orientation using an Azimuth Correction Factor.

A Bifacial Module is disclosed. Applicants' Bifacial Module comprises a glass top member comprising a first periphery, a glass bottom member comprising a second periphery, an encapsulant disposed between said top member and said bottom member. Applicants' Bifacial Module further comprises an edge seal continuously disposed between the glass top member and the glass bottom member, and along said first periphery and said second periphery, where the plurality of electrically interconnected bifacial photovoltaic cells is disposed within the encapsulant.

### BRIEF DESCRIPTION OF THE DRAWINGS

The invention will be better understood from a reading of the following detailed description taken in conjunction with the drawings in which like reference designators are used to designate like elements, and in which:

FIG. 1A illustrates orientation of Applicants' BFM in relation to a rooftop and/or an auxiliary reflector,

FIG. 1B illustrates one embodiment of Applicants' BFM in cross section;

FIG. 1C shows a top view of one embodiment of Applicants' BFM;

FIG. 1D shows a bottom view of one embodiment of Applicants' BFM;

FIG. 2 graphically illustrates a first yearly energy production based upon certain system parameters;

FIG. 3 graphically illustrates a second yearly energy production based upon certain system parameters;

FIG. 4 illustrates the energy production of a (left) vertically mounted BFM in which the front of the module is pointing east and the back is pointing west and (right) a traditional module mounted vertically with its front oriented towards east.

FIG. 5 graphically illustrates Bifacial Gain in Power (BGP) as compared to a monofacial module over a day with a BGE=35%.

### DETAILED DESCRIPTION OF THE PREFERRED EMBODIMENTS

Bifacial-cell-based solar modules (interchangeably referred to hereinafter as bifacial modules, or BFMs) have been shown to produce more power than equally rated monofacial modules, due to the ability of bifacial cells (BFCs) to engage the back-side of the module to harvest sunlight incident on it and convert it to electrical energy.

Configuring an orientation of the BFM in a solar-energy converting system to optimize the electrical output therefrom requires optimization of the solar energy converting system, and should done be with respect to the elements of the ambient light sources which are an important contributor to the solution of this problem, that has been not provided by related art to-date. Applicants disclose solutions to this and other questions by complementing a BFM with an auxiliary reflector comprising a judiciously chosen albedo and orientation with respect to the BFM such that energy production from the so-formed system is maximized.

Bifacial modules, unlike traditional photovoltaic (PV) modules, are structured to capture light on the front and back surfaces of the module. The following patent applications assigned to the common assignee hereof are hereby incorporated herein by reference: Ser. No. 13/682,119 filed on Nov. 12, 2012 and entitled “Encapsulated Solar Energy Concentrator” (docket 132267.00019); Ser. No. 13/680,561 filed on Nov. 19, 2012 and entitled “Light Absorbing Film for Holographic Processing and Method for Using Same” (docket 132267.00021); Ser. No. 13/675,855 filed on Nov. 13, 2012 and entitled “Flexible Photovoltaic Module” (docket 132267.00024); Ser. No. 13/708,160 filed on Dec. 7, 2012 and entitled “Blazed Grating for Solar Energy Concentration” (docket 132267.00028); Ser. No. 13/743,122 filed on Jan. 16, 2013 and entitled “Bussing for PV Module with Unequal-Efficiency BiFacial PV-Cells” (docket 132267.00053); Ser. No. 13/775,744 filed on Feb. 25, 2013 and entitled “Frameless Photovoltaic Volume” (docket 132267.00054); Ser. No. 13/865,805 filed on Apr. 18, 2013 and entitled “Saw-Tooth Shaped Solar Module” (docket 132267.00058); Ser. No. 13/886,119 filed on May 2, 2013 and entitled “Non-Latitude and Vertically Mounted Solar Energy Concentrators” (docket 132267.00059), the disclosure of each of which is incorporated herein by reference).

The total energy output from a BFM is expressed as ETotal=EFront+EBack or as ETotal=EFront*(100%+BGE), where FIG.-of-merit referred to as BGE (“Bifacial Gain in Energy”) is the percentage of gain in electrical energy produced by a BFM in comparison with electrical energy produced by a conventional module employing single-face PV cells (the efficiency of which is equal to the efficiency of the front sides of the BFCs), the BFM and conventional modules being in otherwise equal operational and ambient conditions.

BFMs differ from single-face solar modules in at least the following ways.

1. Electrical calculations such as string and wire sizing, inverter inputs, and overcurrent protection devices should be based on the “Bifacial STC* ratings” (below), according to each module type.
2. System yield calculations are based on STC peak output (less the derating for losses due to, for example, shading, orientation and soiling) multiplied by the Bifacial Gain in Energy (BGE), which is a function of the module used and the local installation conditions.
3. Inverter size for AC output is selected using the peak AC power of the system. Bifacial systems have a higher kWhAC/kWDC, allowing for proportionately smaller inverters and reduced BOS costs.

In certain embodiments, Applicants' BFMs have a greater average backside-to-frontside power ratio of about 0.95 than do prior art BFMs. Moreover, in certain embodiments Applicants' BFM is the only bifacial module configured to eliminate shadowing of the backside of the module.

Virtually all commercially available bifacial modules are electrically interconnected in series. Because these prior art assemblies operate in series, the cells are all operating at the same current, and the module voltage is given by the sum of the individual cell voltages, typically ˜0.5V per cell for silicon at standard testing conditions (STC). Bifacial solar cells operate at the same voltage as a monofacial cell (0.5V) but they produce additional current due to the additional backside generation.

Using first principles from circuit theory:

Bifacial cell Power(W)=ITotal*V=(IFront+IBack)*V=(IFront+IBack)*0.5V

Bifacial Module Power(W)=(#cells in series)*(Bifacial cell Power)

For a 60 cell module:

Bifacial Module Power=(60*0.5V)*(IFront+IBack)=30*(IFront+IBack)

Still following first principle circuit theory and the known fact that elements in series are current limited by the lowest current producing/handling element, then any shadowing of the back bifacial cells necessarily reduces the IBack component for all serially connected bifacial cells in the assembly. This means that the bifacial power output of the module is reduced proportionately to the percentage any cell is shadowed on the backside of the module.

This shadowing effect is a well understood and widely acknowledged PV operational principle. For traditional monocrystalline modules its associated with only the frontside current. For example, if there were no bypass diodes in a traditional PV module, and if the front of the cell is shadowed, it would bring down the total output of the module. Bypass diodes typically disconnect 20 cells in a typical 3 diodes per module configuration and bring down the output of the module by about thirty-three (33) percent for each diode that activates in a 60 cell module.

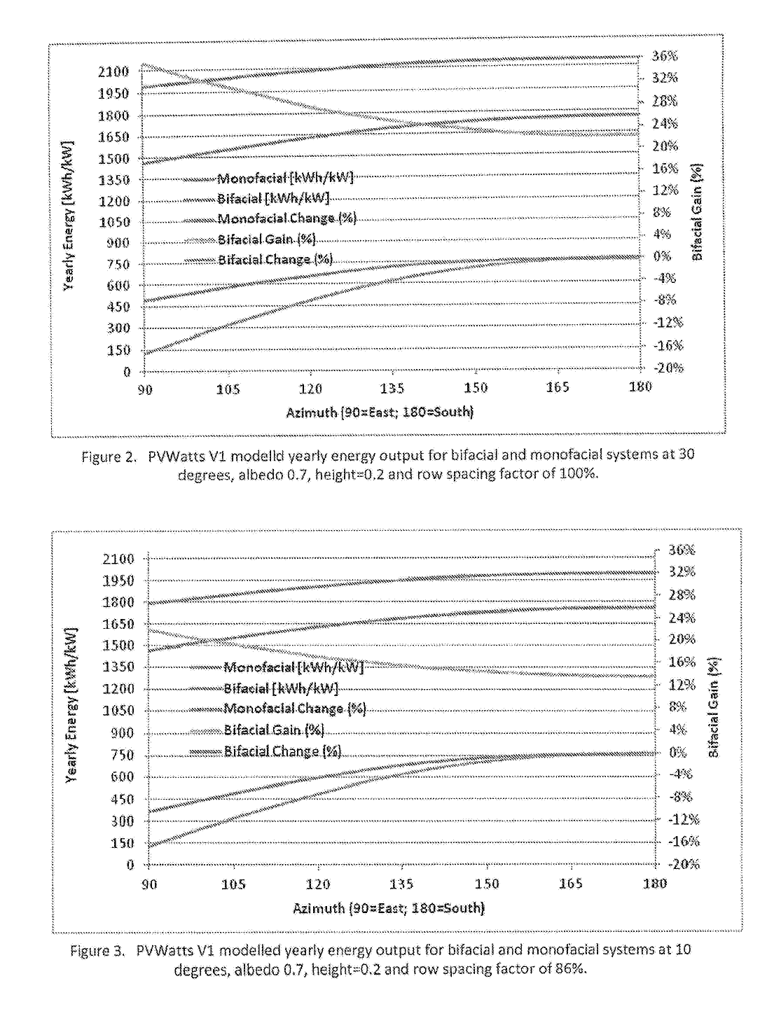

Referring now to FIG. 2, in certain embodiments all potential shadowing that may lead to partial blocking of light directed to the back of the BFM must be avoided. In certain embodiments, special care is taken with Applicants' module racking/support 210 structure to ensure that the module racking/support structure does not shadow the back of the BFM from any source of reflected, ambient light.

In order to achieve a maximum “flash” or STC test value, prior art BFMs include an integral “backsheet” disposed over the back side of the PV cells. When that BFM module is “flashed” from the front side during QA/QC testing, the flashed light is directly received by the front-side PV cells. That flashed light is reflected onto the back-side PV cells by the integral backsheet.

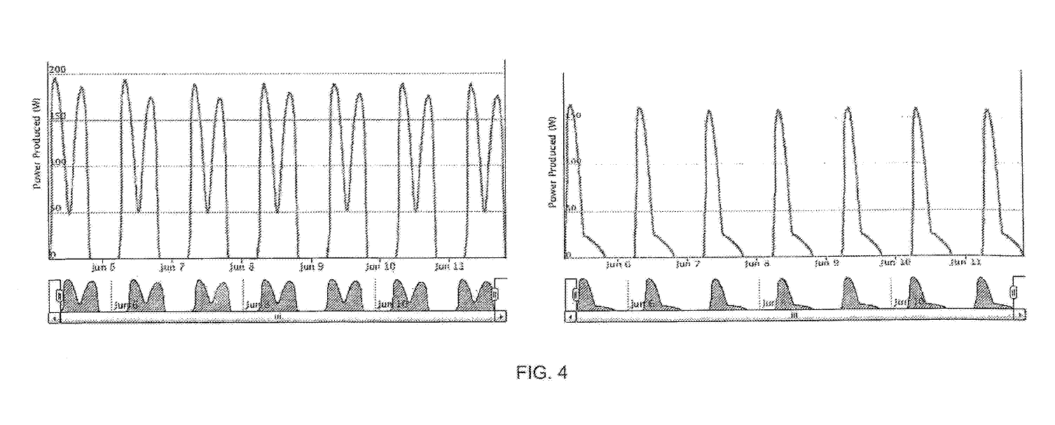

Referring once again to FIG. 3, prior art solar panels 300, including BFMs, utilize a frame 310. In certain embodiments, frame 310 is formed from a metal. Referring once again to FIG. 2, Applicants' BFM module 220 comprises a rear glass substrate but no frame for the BFM. In certain embodiments, Applicants' BFM comprises a frameless module comprising bifacial, crystalline, solar cells.

Use of such a rigid, all glass structure, was a substantial technical challenge because bifacial cells are extremely brittle due to their crystalline structure, and the lack of full metallization on the backside (which supports and binds the cell together in the case of panel breakage).

A person skilled in the art will appreciate that use of a glass mechanical structure in combination with bifacial cells would complicate manufacturing and increase a manufacturing breakage rate. Nevertheless, the use of a glass enclosure results in many advantages.

The texture glass helps create a diffuse/scattering effect which helps increase the bifacial effect of the module while maintaining a high transmission rate. This is achieved by homogenizing the light available to interact with the background, providing more uniform light to the back of the module. If used on a monofacial module, this provides more uniform light behind the module for applications such as carports, awnings, etc but does not affect the performance of the module.

Texture glass is essential for a glass/glass module fabrication because it aids in evacuating the air and other chemicals released during the vacuum lamination process. Since scrim sheets cannot be used, and scrim sheets add rigidity and help evacuate air during the vacuum lamination process, a glass/glass module fabricated without the texturing in the glass would suffer from air voids, incomplete evacuation, and other lamination defects. This texturing is present on both surfaces of each rigid substrate but it is only needed in the surface that faces the PV cells.

An edge seal around the module is an active element for weather protection. In certain embodiments, Applicants' edge seal comprises desiccating particles dispersed in a seal composition that when cured forms an elastomeric matrix filled with desiccating particles. In a matrix of butyl rubber, the rubber acts like a traditional seal preventing moisture intrusion. Addition of the desiccating particles extracts moisture from interior of the module. Through the naturally occurring daily temperature differential, the desiccating seal is able to expel the humidity from the module and edge seal to the exterior of the module.

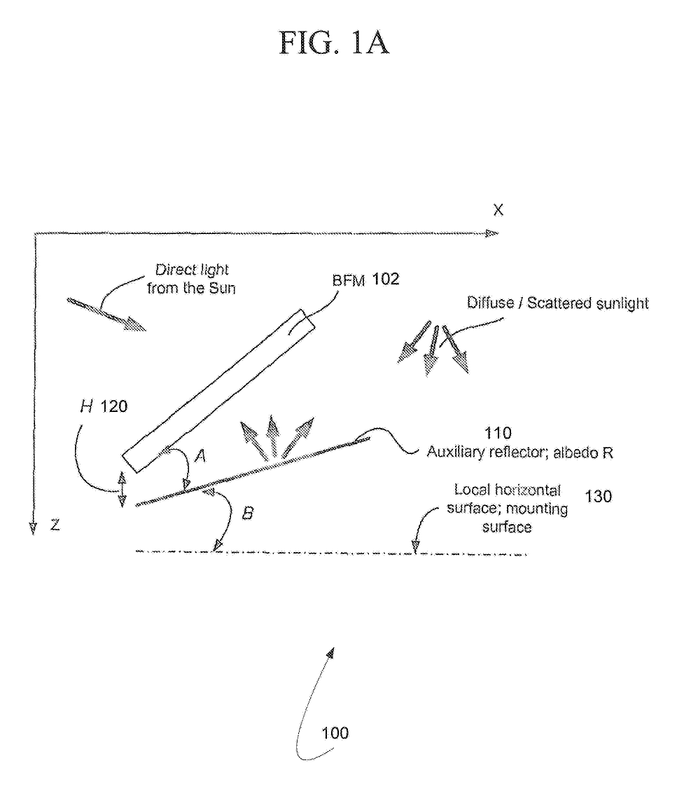

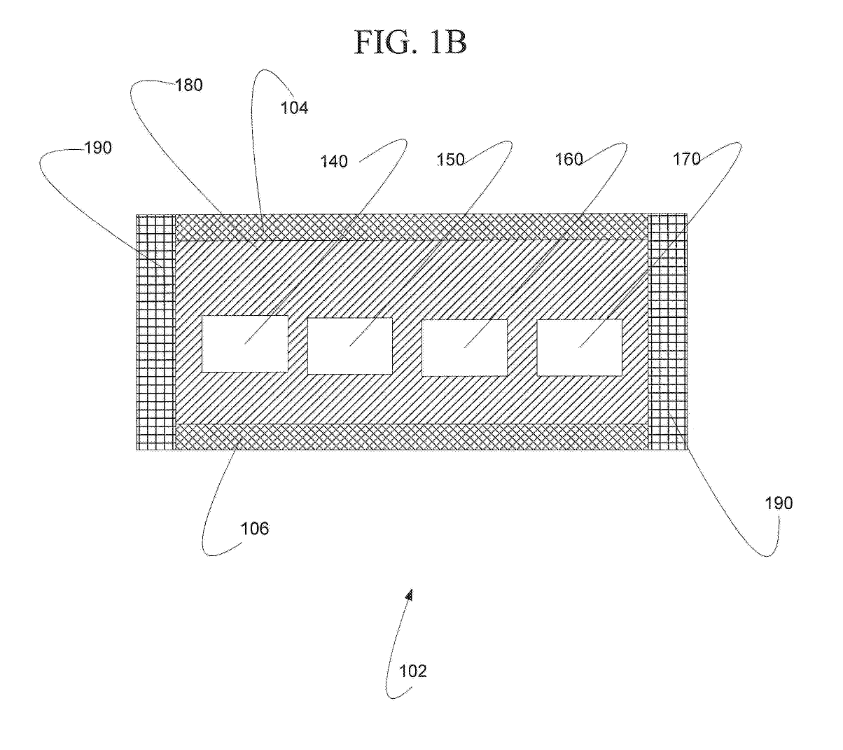

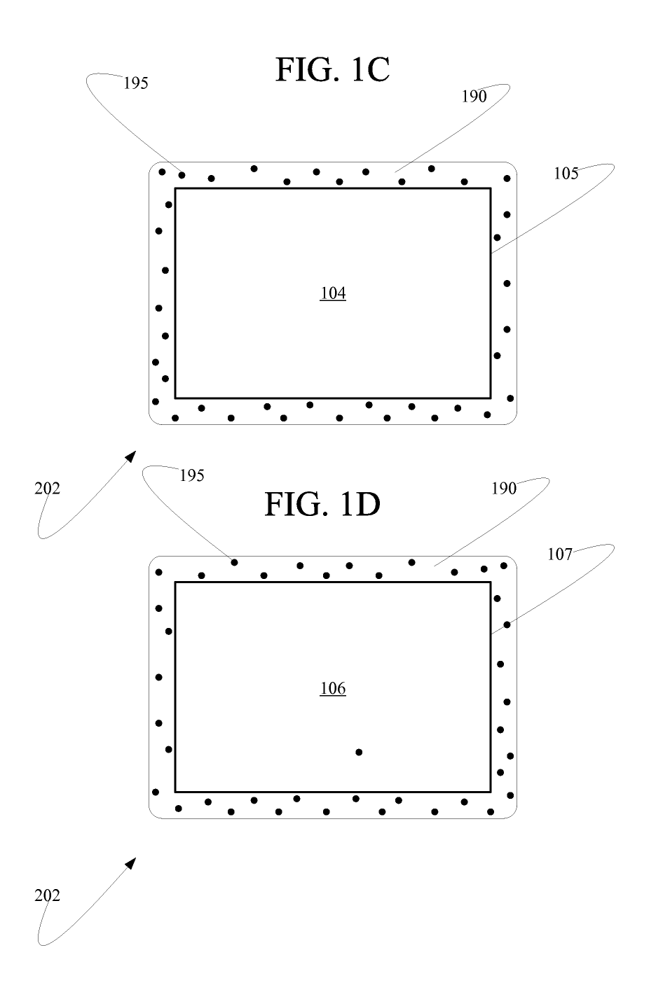

In the illustrated embodiment of FIG. 1B, Applicants' BFM comprises a plurality of individual PV cells 140, 150, 160, and 170. In certain embodiments, Applicants' BFM comprise more than four PV cells.

Further in the illustrated embodiment of FIG. 1B, the plurality of PV cells are disposed within an encapsulant 180. Those skilled in the art will appreciate that FIG. 1B does not show the electrical interconnects between the plurality of PV cells.

In certain embodiments, the top member 104 of BFM 102 comprises a glass sheet. In certain embodiments, the bottom member 106 comprises a glass sheet.

Applicants' BFM further comprises edge seal 190. Applicants have found that use of an edge seal containing a desiccant reduces the amount of water reaching inside the photovoltaic panels. Referring now to FIGS. 1B, 1C, and 1D, in certain embodiments Applicants' BFM comprises an edge seal 190 continuously disposed between glass top member 104 and glass bottom member 106, and along the first periphery 105 and the second periphery 107.

In the illustrated embodiment of FIGS. 1C and 1D, edge seal 190 comprises a plurality of desiccating particles 195 disposed therein. In certain embodiments, desiccating particles 195 are present in edge seal 190 at a level between about 0.01 to about 10 weight percent.

The diffusion of water through the edge seal can be described as a one-dimensional Fickian diffusion. Fick's first law relates the diffusive flux to the concentration under the assumption of steady state. It postulates that the flux goes from regions of high concentration to regions of low concentration, with a magnitude that is proportional to the concentration gradient (spatial derivative), or in simplistic terms the concept that a solute will move from a region of high concentration to a region of low concentration across a concentration gradient. In one (spatial) dimension, the law is:

$$J = - D \frac{\partial φ}{\partial x}$$

where:
J is the “diffusion flux” [(amount of substance) per unit area per unit time], for example

$$( \frac{mol}{{m}^{2} s} ) .$$

J measures the amount of substance that will flow through a small area during a small time interval;
D is the diffusion coefficient or diffusivity in dimensions of [length² time⁻¹], for example

$$( \frac{{m}^{2}}{s} ) ;$$

φ (for ideal mixtures) is the concentration in dimensions of [amount of substance per (unit volume], for example

$$( \frac{mol}{{m}^{2}} ) ;$$

χ is the position [length], for example [symbol]
D is proportional to the squared velocity of the diffusing particles, which depends on the temperature, viscosity of the fluid and the size of the particles

In certain embodiments, Applicants BFMs utilize an edge seal comprising desiccating particles disposed therein. In certain embodiments, the desiccating particles comprise a desiccant that reacts irreversibly with the water, for example Calcium Oxide. In other embodiments, the desiccating particles comprise a desiccant that absorbs water reversibly, for example Zeolites.

In the reversible desiccant particle embodiments, the heat of the day time can cause desorption of the water molecules bound to the desiccant. That released water is exhausted from the edge seal back into the environment without ever reaching the interior of Applicants' BFM.

Using this seal composition is important for long term system viability. No sealing technology is one hundred percent (100%) effective, and incorporating an ability to draw out whatever moisture penetrates the module is very important over the lifetime of the module.

Applicants' frameless modules do not need to be grounded/bonded, as prior art modules need to be, because Applicants' frameless modules comprise no exposed conductive elements, such as a frame or other metal parts.

Applicants' frameless modules are not subject to high potential induced degradation (PID) under standard mounting conditions. Under similar conditions, bifacial modules comprising frames and poorer humidity protection suffer from PID.

A framed module wherein individual PV cells are interconnected in the traditional serially connected manner has a potential differential between its cells and the grounded frame and front and back substrates. As time goes by, the encapsulating material, usually the encapsulant, absorbs humidity from the environment making it more conductive which leads to increased electron flow between the cells, and the frame and substrates. This electron/ion flow damages the cells and lowers the output of the whole assembly. Applicants eliminate both the potential differential degradation at the cell level, and the encapsulant degradation resulting from use of Applicants' active edge seal material and the glass/glass structure.

In certain embodiments, Applicants use an extra layer of encapsulant between the cells and the glass to cushion the cells thereby guarding against cell breakage but increasing the cost of building the module and lowering the manufacturing efficiency. The BFMs and traditional modules utilizing a back sheet usually have the encapsulant built in to one side of the backsheet to aid in manufacturing efficiency and cost. In certain embodiments, Applicants' encapsulant is also highly textured to aid in the evacuation process during lamination which is not necessary in standard module production. This is necessary because the glass on glass package only allows for evacuation around the perimeter of the module.

Longer lamination times and specialized non standardized equipment is needed for the lamination of the Applicants' BFMs due to the reduced thermal transfer thought the glass substrates and special vacuum considerations.

In certain embodiments, Applicants' BFM comprises a Jbox comprising the smallest profile in the BFM industry. All of the components in Applicants' junction box/power electronics/interconnection are configured to not interfere with either direct light, or reflected light, directed onto cells on both the front and back of the module.

In certain embodiments and in order to eliminate any shadowing from the Jbox, Applicants' BFM disposes PV cells over only about ninth-five percent of the available surface area of either the front portion, or the rear portion, of a BFM. The remaining five percent (5%) of the front side and rear side surface area is reserved for Jbox placement. As a result, the front side Jbox and a rear side Jbox cannot shadow any of the PV cells in the BFM. In summary, Applicants' BFM does not comprise a Jbox disposed directly over or directly under any of the plurality of electrically-interconnected bifacial photovoltaic cells.

In marked contrast, prior art monofacial and bifacial modules utilize about one hundred percent (100%) of the front side (both monofacial and bifacial) and rear side (bifacial) surface area of the module for placement of PV cells. As a result, the junction box must necessarily be placed directly over, or directly under one or more of the PV cells. That Jbox will necessarily shadow certain of the PV cells disposed in the BFM.

In certain embodiments, Applicants rear side PV cells produce about ninety percent (90%) to ninety five percent (95%) of the relative power performance of the front side PV cells. Prior art BFMs using either white or black backsheets produce about ten percent or less power from the rear-side PV cells relative to the power performance of the front side PV cells.

This means a 10% bifacial module would produce only 10/90=11% of the backside output that Applicants' BFM produces.

Applicants' BFM utilizes highly efficient bifacial silicon cells 140, 150, 160, 170, that convert to energy the light that strikes both the front and the back of the bifacial panels. Applicants' bifacial panels are able to generate electrical energy using not only sunlight that directly strikes the panels, but also sunlight that is reflected from the surface on which the panels are installed and other scattered light from ground and ambient sources.

Applicants' solar panels are roughly equally efficient on the front 104 and back side 106, meaning that up to 50 percent of the energy produced by the photovoltaic generation system is attributable to light that is absorbed by the back side of each solar panel. Moreover, Applicants' solar panels can produce approximately 40 percent more energy than traditional monofacial panels when installed in an optimal standard configuration over a highly-reflective surface. Unlike any other solar module currently on the market, the power generated from the back side of Applicants' module will equal at least 90 percent of the power generated from the front side.

Currently, the most effective reflective surfaces available for rooftop installations of Applicants' photovoltaic generation systems are special-purpose impermeable membranes that are affixed to the roof of a building. These reflective membranes are manufactured by a number of suppliers. The reflectivity of these special-purpose membranes is generally established through certifications by industry-rating institutions, such as the Cool Roof Rating Council (CRRC) or the ENERGY STAR rating program administered by the Department of Energy and the Environmental Protection Agency. CRRC, in particular, publishes radiative data on roof surfaces.

The reflectivity of a surface to sunlight is measured as the “albedo” of the surface, with a perfectly reflective surface having an albedo of 100 percent and a perfectly non-reflective surface having an albedo of 0 percent. Developer recommends that its panels be installed over CRRC- or ENERGY STAR-compliant (i.e., high-albedo) roof membranes in order to capture energy efficiencies provided by the bifacial design of its panels.

FIG. 1A shows the components of the solar irradiance that affect the performance of an embodiment of the solar system of the invention employing Applicants' BFM 102 and an auxiliary reflector 110. Generally, when the back of the BFM is irradiated, the overall output of the module is increased. By determining the spatial orientation of the BFM that maximizes the collection (by the backside of the module) of sky-scattered/diffuse sunlight, the amount of sunlight to which the backside of the BFM is exposed can be increased. This effect can be further enhanced by cooperating, with the BFM, an auxiliary reflector having sufficiently high albedo (or surface reflectivity, R) such as to form a solar system according to an embodiment of the invention.

Applicants have found that light reaching the backside of the BFM is directly related to the height H at which the module is installed over the auxiliary reflector and the angle A formed by the backside surface of the BMF and the surface of the auxiliary reflector (a tilt angle). While the auxiliary reflector can be an element installed over a mounting surface used for installation (such as a ground or a such as an ENERGY STAR™ roof, snow, or horizontal surface coated with white paint), in a specific implementation the auxiliary reflector can be the roof used for mounting the system itself, for example. In this case, angle B of FIG. 1 may be equal to zero degrees.

The energy output of the module will vary from the Bifacal-STC in the same way that standard modules vary from standard STC. Use the following steps to calculate and optimize the Bifacial Gain in Energy.

Step #1: Choose the highest possible Surface Reflectivity/Albedo: The optimization of the solar reflectivity or albedo reflected light of the surface under the module installation controls the amount of light that is reflected to the backside of the solar module. Optimization of this surface is the predominant factor for increased module output. Use crushed white rock, bright white paint, or an ENERGY STAR™ roof to define an auxiliary reflector for best results.

Step #2: Place the BFM at 0.15 m (0.5 ft) or farther above the reflective surface: Placing the modules in a standard configuration may be too close to the roof surface creating a self-shading effect, blocking available albedo light.

Table 1 shows the relationship between the albedo of the reflective surface and the height of the BFM above the reflective surface. For example, using a reflective surface having an albedo of 0.7, and placing the height of the lowest point of the BFM a meter above the reflective surface, results in an increase of 36.17 percent in the annual energy generated.

TABLE 1

Height of the lowest point
above the roof (m) or Installation

| Albedo | 0.15 | 0.2 | 0.3 | 0.5 | 0.7 | 1 |
|---|---|---|---|---|---|---|
| 0.15 | 13.21 | 13.75 | 14.82 | 16.98 | 19.14 | 22.38 |
| 0.3 | 14.88 | 15.49 | 16.71 | 19.14 | 21.57 | 25.22 |
| 0.5 | 16.65 | 17.33 | 18.70 | 21.42 | 24.14 | 28.22 |
| 0.7 | 21.35 | 22.22 | 23.96 | 27.45 | 30.94 | 36.17 |
| 0.85 | 22.37 | 23.28 | 25.11 | 28.77 | 32.42 | 37.90 |

Table 2 recites bifacial gain in energy in percentage for a 60 cell bifacial module/system mounted at A=30 degrees and facing south, B=0. High albedo and higher module tilts maximize the bifacial gain. (60 Cell Bifacial Gain in Energy (Backside Production) in (%) for south facing modules mounted at 30 degrees).

TABLE 2

Height of the lowest point
above the roof (m) or Installation

| Albedo | 0.15 | 0.2 | 0.3 | 0.5 | 0.7 | 1 |
|---|---|---|---|---|---|---|
| 0.15 | 13.21 | 13.75 | 14.82 | 16.98 | 19.14 | 22.38 |
| 0.3 | 14.88 | 15.49 | 16.71 | 19.14 | 21.57 | 25.22 |
| 0.5 | 16.65 | 17.33 | 18.70 | 21.42 | 24.14 | 28.22 |
| 0.7 | 21.35 | 22.22 | 23.96 | 27.45 | 30.94 | 36.17 |
| 0.85 | 22.37 | 23.28 | 25.11 | 28.77 | 32.42 | 37.90 |

Table 3 recites bifacial gain in energy in percentage for a 48 cell bifacial module/system mounted at A=30 degrees and facing south, B=0. (48 Cell Bifacial Gain in Energy (Backside Production) in (%) for south facing modules mounted at 30 degrees).

TABLE 3

Height of the lowest point above
the roof (m) or Installation

| Albedo | 0.15 | 0.2 | 0.3 | 0.5 | 0.7 | 1 |
|---|---|---|---|---|---|---|
| 0.15 | 14.09 | 14.67 | 15.82 | 18.12 | 20.43 | 23.88 |
| 0.3 | 15.88 | 16.53 | 17.83 | 20.42 | 23.02 | 26.91 |
| 0.5 | 17.77 | 18.5 | 19.95 | 22.85 | 25.76 | 30.11 |
| 0.7 | 22.78 | 23.71 | 25.57 | 29.29 | 33.02 | 38.60 |
| 0.85 | 23.87 | 24.85 | 26.80 | 30.70 | 34.60 | 40.45 |

The data summarized in Tables 1, 2, and 3, estimate the amount of additional energy that will be produced by the system of the invention due to the use of a glass/glass support, frameless, bifacial cell and collection of radiant energy at the backside of the BFM.

It was empirically determined that, other than for fresh snow conditions, the bifacial gain is maximized (as seen in Table 2 and 3) when the BFM of the invention is used in cooperation with a commercially available roof coating such as those the examples of which are summarized in Table 4 and 5.

TABLE 4

| | | | | SOLAR | | THERMAL | | | |
|---|---|---|---|---|---|---|---|---|---|
| CRRC | | | | REFLECTANCE | | EMITTANCE | | 5 RI [symbol] | |
| PROD. | MANUFACTURER BRAND | | | | 3 | | 3 | | 3 |
| ID [symbol] | MODEL [symbol] | PRODUCT TYPE [symbol] | COLOR [symbol] | Initial [symbol] | year [symbol] | Initial [symbol] | year [symbol] | Initial [symbol] | year [symbol] |
| 1116-0001 | Ranotit Belgam NV. Attorplan | Membrane Single Ply | Bright White | 0.91 | pending | 0.84 | pending | 115 | pending |
| | F 35276 Attorbright 1920-1.5 mm, | Thermoplastic and | | | | | | | |
| | 2.0 mm, 1.5 mm with fleeceback | Thermoset Roofing | | | | | | | |
| 1116-0002 | Ranotit Belgam NV. Attorplan | Membrane Single Ply | Bright White | 0.91 | pending | 0.85 | pending | 115 | pending |
| | F 35276 Attorbright 2009-1.5 mm | Thermoplastic and | | | | | | | |
| | | Thermoset Roofing | | | | | | | |
| 1116-0004 | Ranotit Belgam NV. Attortec | Membrane Single Ply | Bright White | 0.90 | pending | 0.85 | pending | 114 | pending |
| | F 35196-2.5 mm, 1.3 mm | Thermoplastic and | | | | | | | |
| | | Thermoset Roofing | | | | | | | |
| 0628-0011 | Carliste Construction Materials | Membrane Single Ply | Bright White | 0.88 | 0.75 | 0.89 | 0.90 | 111 | 93 |
| | Incorporated Spectre-Weld | Thermoplastic and | | | | | | | |
| | TFO White | Thermoset Roofing | | | | | | | |
| 0610-0001 | Duro-Last Roofing Inc. Duro-Last | Membrane Single Ply | Bright White | 0.88 | 0.68 | 0.87 | 0.84 | 111 | 82 |
| | White | Thermoplastic and | | | | | | | |
| | | Thermoset Roofing | | | | | | | |
| 0610-0010 | Duro-Last Roofing Inc. Duro-Last | Membrane Single Ply | Bright White | 0.87 | pending | 0.89 | pending | 110 | pending |
| | Duro-Fleece | Thermoplastic and | | | | | | | |
| | | Thermoset Roofing | | | | | | | |
| 0798-0002 | Viridian Systems. HK 5000/5001 | Membrane Single Ply | Bright White | 0.87 | 0.76 | 0.87 | 0.84 | 110 | 93 |
| | White | Thermoplastic and | | | | | | | |
| | | Thermoset Roofing | | | | | | | |
| 1032-0002 | SR Products SR Products | Membrane Single Ply | Bright White | 0.87 | 0.76 | 0.87 | 0.84 | 110 | 93 |
| | Sign | Thermoplastic and | | | | | | | |
| | | Thermoset Roofing | | | | | | | |
| 0866-0001 | Ecotogy Roof Systems. White | Membrane Single Ply | Bright White | 0.87 | 0.76 | 0.87 | 0.84 | 110 | 93 |
| | Elvaloy Roof System | Thermoplastic and | | | | | | | |
| | ERS-3000 FS | Thermoset Roofing | | | | | | | |
| 0670-0025 | Mute-Hide Products Co., Inc.; | Membrane Single Ply | Bright White | 0.87 | 0.61 | 0.95 | 0.86 | 111 | 72 |
| | Mute-Hide PVC | Thermoplastic and | | | | | | | |
| | | Thermoset Roofing | | | | | | | |
| 0844-0003 | Commerciat Innovations, Inc.; | Membrane Single Ply | Bright White | 0.87 | 0.71 | 0.85 | 0.84 | 110 | 86 |
| | Solar Brite White KEE | Thermoplastic and | | | | | | | |
| | | Thermoset Roofing | | | | | | | |
| 0844-0004 | Commerciat Innovations, Inc.; | Membrane Single Ply | Bright White | 0.87 | 0.76 | 0.87 | 0.84 | 110 | 93 |
| | WeldTide White PVC | Thermoplastic and | | | | | | | |
| | | Thermoset Roofing | | | | | | | |
| 0640-0001 | IB Roof Systems; IB Roof Systems | Membrane Single Ply | Bright White | 0.87 | 0.74 | 0.88 | 0.89 | 110 | 91 |
| | White PVC | Thermoplastic and | | | | | | | |
| | | Thermoset Roofing | | | | | | | |
| 0676-0090 | GAF EverGuard ® | Membrane Single Ply | Bright White | 0.87 | 0.76 | 0.87 | 0.84 | 110 | 93 |
| | PVC Smooth White | Thermoplastic and | | | | | | | |
| | | Thermoset Roofing | | | | | | | |

TABLE 5

| | | | | SOLAR | | THERMAL | | | |
|---|---|---|---|---|---|---|---|---|---|
| CRRC | | | | REFLECTANCE | | EMITTANCE | | 5 RI [symbol] | |
| PROD. | MANUFACTURER BRAND | PRODUCT | | | 3 | | 3 | | 3 |
| ID [symbol] | MODEL [symbol] | TYPE [symbol] | COLOR [symbol] | Initial [symbol] | year [symbol] | Initial [symbol] | year [symbol] | Initial [symbol] | year [symbol] |
| 0646-0022 | APOC/Gardner-Gibson Inc.; | Field-Applied | Bright White | 0.95 | pending | 0.89 | pending | 122 | pending |
| | RoofTender 800 Bright White | Coatings; Acrylic | | | | | | | |
| 0646-0021 | APOC/Gardner-Gibson Inc.; APOC | Field-Applied | Bright White | 0.95 | pending | 0.89 | pending | 122 | pending |
| | 256 White | Coatings; Acrylic | | | | | | | |
| 0646-0029 | APOC/Gardner-Gibson Inc.; STA- | Field-Applied | Bright White | 0.94 | pending | 0.88 | pending | 120 | pending |
| | KOOL 800 White | Coatings; Acrylic | | | | | | | |
| 0646-0020 | APOC/Gardner-Gibson Inc.; Black Jack | Field-Applied | Bright White | 0.94 | pending | 0.88 | pending | 120 | pending |
| | Maxx-Cool White | Coatings; Acrylic | | | | | | | |
| 1124-0001 | APV Engineered Coatings; APV | Field-Applied | Bright White | 0.93 | pending | 0.89 | pending | 118 | pending |
| | eCoolRoof P-1498 & P-1494 | Coatings; Acrylic | | | | | | | |
| 0616-0041 | Quest Construction Products dba United | Field-Applied | Bright White | 0.92 | pending | 0.87 | pending | 117 | pending |
| | Coatings and Hydro-Stop; RoofMata | Coatings; Acrylic | | | | | | | |
| | High Reflectant Plus | | | | | | | | |
| | White | | | | | | | | |
| 0614-0042 | Quest Construction Products dba United | Field-Applied | Bright White | 0.92 | pending | 0.86 | pending | 117 | pending |
| | Coatings and Hydro-Stop; Hydro-Stop | Coatings; Acrylic | | | | | | | |
| | Premium High Reflectant Plus | | | | | | | | |
| | White | | | | | | | | |
| 0676-0023 | GAF Topecot ® | Field-Applied | Bright White | 0.91 | 0.78 | 0.87 | 0.89 | 115 | 97 |
| | EneryCore™ Elastomeric Coating | Coatings; Acrylic | | | | | | | |
| | (white) | | | | | | | | |
| 0646-0027 | APOC/Gardner-Gibson Inc.; APOC | Field-Applied | Bright White | 0.91 | pending | 0.89 | pending | 116 | pending |
| | 256 FR White | Coatings; Acrylic | | | | | | | |
| 0646-0023 | APOC/Gardner-Gibson Inc.; APOC | Field-Applied | Bright White | 0.90 | pending | 0.89 | pending | 114 | pending |
| | 232 FR White | Coatings; Acrylic | | | | | | | |
| 0646-0033 | APOC/Gardner-Gibson Inc.; HP 425 | Field-Applied | Bright White | 0.90 | 0.77 | 0.87 | 0.90 | 114 | 96 |
| | White | Coatings; Acrylic | | | | | | | |
| 1054-0001 | NuTech Paint LLC, NXT COOL ZONE | Field-Applied | Bright White | 0.90 | 0.86 | 0.87 | 0.88 | 114 | 108 |
| | Gloss White | Coatings; Acrylic | | | | | | | |
| 1094-0002 | West Development Group; SmartRoof | Field-Applied | Bright White | 0.90 | pending | 0.89 | pending | 114 | pending |
| | 1-Coat High Solids Silicone Roof | Coatings; Acrylic | | | | | | | |
| | Coating | | | | | | | | |
| 0646-0026 | APOC/Gardner-Gibson Inc.; APOC | Field-Applied | Bright White | 0.90 | pending | 0.89 | pending | 114 | pending |
| | 252 FR White | Coatings; Acrylic | | | | | | | |
| 1094-0001 | West Development Group; System 14 | Field-Applied | Bright White | 0.90 | 0.59 | 0.89 | 0.88 | 114 | 70 |
| | HSS 535 Solvent-Free Silicone Coating | Coatings; Acrylic | | | | | | | |

The combination of Applicants' BFM and an auxiliary reflector formed with the use of a cool roof coatings/material (from Tables 4, 5) or any other material with a large reflectivity in the spectral range accepted by of the PV BFC used in the BFM forms a combined solar energy converting system of the invention characterized by maximized energy output [kwh/kw].

Other system factors that must be taken into account include:
the BFM tilt angle (the notation [symbol] is used interchangeably with A, for an angle between the BFM and the auxiliary reflector of FIG. 1), accounted for by the tilt correction factor shown in Table 6;
the solar azimuth correction factor (angle between the direction to the south and direction in which the BFM is faced) accounted for in Table 7; and
the spacing between the immediately adjacent rows in which the multiple BFMs are arranged, accounted by a row spacing correction factor shown in Table 8.

TABLE 6

| | Installation Tilt Angle (degrees) | | | | | |
|---|---|---|---|---|---|---|
| | θ ≦ 10° | θ = 15° | θ = 20° | θ = 25° | θ ≧ 30° | θ = 90° |
| Tilt | 71% | 79% | 86% | 94% | 100% | See |
| Correction | | | | | | below |
| Factor | | | | | | |

TABLE 7

| | Azimuth deviation from south (degrees) | | | | | | | | | |
|---|---|---|---|---|---|---|---|---|---|---|
| | 0 | 10 | 20 | 30 | 40 | 50 | 60 | 74 | 80 | 90 |
| Azimuth | 100% | 100% | 102% | 106% | 111% | 118% | 126% | 137% | 148% | 162% |
| Correction Factor | | | | | | | | | | |

TABLE 8

| | Row spacing as a function of the shadow | | | | | | |
|---|---|---|---|---|---|---|---|
| | design time on December 21st | | | | | | |
| | 9:00 AM | 9:30 AM | 10:00 AM | 10:30 AM | 11:00 AM | 11:30 AM | 12:00 PM |
| Row spacing | 100.0% | 97.6% | 95.3% | 93.0% | 90.6% | 88.3% | 86.0% |
| correction factor | | | | | | | |

An embodiment of the method of the invention to maximize the performance of the system includes the following:

Using data such as the data from Tables 2 or 3 (that are BFM-dependent and BFM-orientation dependent), finding the intersection of the Albedo and the Height of the lowest point of the module above the reflective surface of the auxiliary reflector (for single row module applications) or the Height/Width ratio for larger and overhead installations.

Determining the BGE for a bifacial module/system mounted at a tilt of A degrees with respect to the auxiliary reflector (in case of Tables 2, 3: A=30; B=0) and an azimuth of D degrees (in case of Table 2, 3, D=180, BFM facing south) given a certain ground albedo and module/system height. In the case when a mounting roof is used as an auxiliary reflector, choosing surface coating materials with high surface reflectivity/albedo such as those shown in Tables 4 and 5, results in a higher bifacial gain.

Determining a Tilt correction factor (%) using Table 6.

Determining an Azimuth correction factor (%) using Table 7.

Determining a Row spacing factor (%) using Table 8.

Flat Rooftops—Row Spacing: Rows should be spaced slightly larger than the typical row spacing of noon on December 21st. The BGE is reduced linearly up to 14% at row spacing of noon on December 21st vs. 9 am. (Ex. For a B250 and row spacing of 10:30 am on December 21st with a SR of 0.5 and height of 0.5 m, the BGE would be 7% less than 21.42% or 19.92%). The minimum row spacing should be approximately 0.5 m to increase the sunlight between the rows, especially for tilt angles less than 15 degrees.

Flat Rooftops—Tilt: the data in Tables 2 and 3 were calculated for an optimum mounting angle (30 degrees), near latitude (3 w degrees) mounting conditions. For reduced tilt angles, increasing the height under the module will optimize the BGE.

Flat Rooftops—Modules In Portrait: The data in Tables 2 and 3 are derived to calculate BGE based on rows oriented in landscape. For rows in portrait, divide the height of the lowest point of the module by 1.65 to accommodate for the additional shading of a portrait module. (Ex. a row in portrait at 0.5 m above roof will perform the same as a landscape row only 0.3 m above the roof)

Overhead Structures—Canopy/Carports, and Installations with Multiple rows per Structure: In Table 2, use the Height/Width of the array to estimate the BGE, instead of the lowest point of a module above the installation surface. The width is defined as the length of the array in the North-South direction. The height is defined as the lowest point of a module above the installation surface. Apply all other corrections factors (row spacing, angle, etc.).

Vertical applications: Privacy Fences, Rooftop screens, Etc.: The bifacial module will produce the sum of two monofacial modules back to back. Standard production simulation software will provide accurate results by simulating the addition of two monofacial modules facing opposite directions. The east/west vertical installation shown below will yield up to a 95% backside energy gain compared to a standard module.

The BEGFINAL (%) is then given as:

BEGFINAL (%)=BEGinitial*(Tiltfactor)*(Azimuthfactor)*(Rowfactor)

The total module energy output will be the:

ETotal=EFront+EBack=EFront*(100%+BGE)

EFront can be simulated as the monofacial equivalent of the front of the bifacial module and can be simulated by standard industry tools such as NREL's PVWatts, NREL's SAM, PVSyst, Folsom Lab's Helioscope, etc.

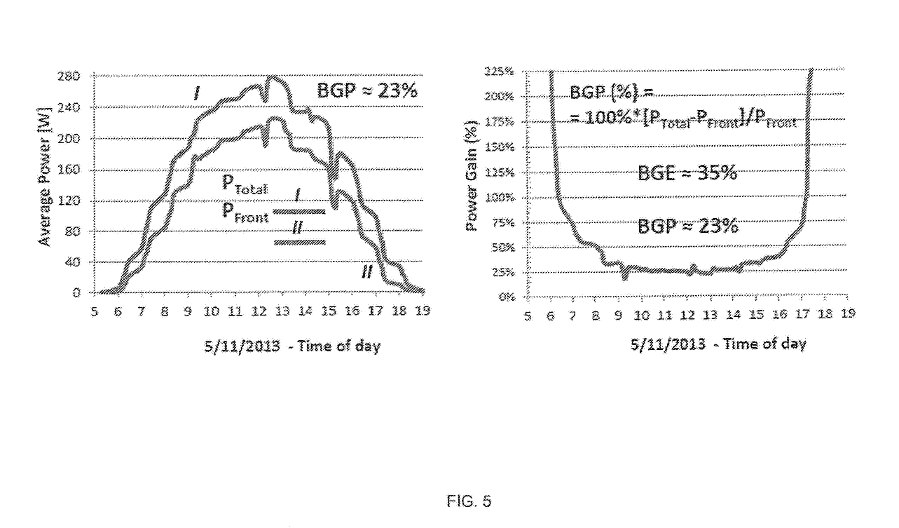

FIG. 4 illustrates weekly power output for an East/West vertical installation of a bifacial module (LEFT) and a monofacial module (RIGHT).

### Example

Modeling was done for monofacial and bifacial systems structured according to the embodiment of FIG. 1 and assumed to be situated in Tucson, Ariz. and mounted at ˜30 degrees on a horizontal white roof with an albedo of 0.7, at a height of the lowest point of the BFM above the roof of 0.2 m. The azimuth was varied from south (180 degrees) to east (90 degrees). The plots representing the output of the system in kWh/kW and the loss from the peak yearly production are shown in FIG. 2.

As can be observed the loss of production associated from moving the modules away from true south is as high as 17%, while for bifacial system it is only 7%. FIG. 3 shows the same model run for a tilt value of 10 degrees and a row spacing factor of 86% (December 21^{st} solar noon spacing), the “gain” achieved by tilting the modules from south is reduced because overall there was less light to the back of the module.

By pointing a module in a specific direction, East or West, the energy production at a particular time of day can be maximized more so than with just the white roof. This means than in locations such with tiered/time of day kWh pay schedules or at time of high energy consumptions, the module energy can be design to maximize the payout or offset the maximum amount of time of use consumption. This is called time of use (TOU) optimization. By combining east/west and south facing tilted modules, the total production time over the day can also be maximized for the system.

High Bifacial Ratio. It is important to note that the uniform effects showed for the mixed field in this document are possible due to the high bifacial ratio (referred to herein as “bifaciality”) of Prism Solar modules. The Bifacial Ratio is defined as

Bifacial Ratio=(Module Back Efficiency)/(Module Front Efficiency)×100

The bifacial ratio is the simple ratio of the back and front module efficiencies. Applicants' “bifaciality” is about 90% to 95%. For the case of a monofacial cell the bifaciality=0. The mixed field, uniform energy effect is lessened as the ratio decreases.

Inverter Sizing and Selection. In order to properly size an inverter for an array it may be necessary to understand the relationship between the BGE and Peak Power output (PMAX). Inverters are selected based on the expected peak DC power output. To prevent undersizing the inverters and AC system, it is important to take into consideration the total amount of power produced by the module, PMAX=PTotal=PFront+PBack. The Bifacial Gain in Power (BGP) as compared to a monofacial module over a day with a BGE=35% is shown in FIG. 5, showing the empirically determined total and frontside power outputs for a Prism Solar B245 bifacial system (LEFT) and the instantaneous BGP (%) for the same system (RIGHT); the BGE for the day was ˜35%.

For south facing, single row module applications, the BGP can then be estimated as:

BGP=65%*BGEtilt

To determine the Peak Power output (PMAX) production to size your system inverters, use the following equation:

Pmax=(Expected Peak Front DC Power)*[BGP+100%]

For example from Table 3, a single module array of B200 modules, 0.3 m above an aged energy star roof (SR=0.7) at 30 degrees would result in a BGE of 25.57%. 65% of the BGE value would be expected as the peak increase in instantaneous bifacial gain in power (BGP) from the back of the module. The PMAX of this system would be:

Pmax=(Expected Peak Front DC Power)*[(25.57%)*65%+100%]

=(Expected Peak Front DC Power)*116.62%

Please note that the Pmax is a calculated value, the actual instantaneous value can vary depending on local conditions. The bifacial peak power can exceed the calculated peak power (Pmax) due to snow, cloud edge effects, reflections, local elevation, etc.

While the preferred embodiments of the present invention have been illustrated in detail, it should be apparent that modifications and adaptations to those embodiments may occur to one skilled in the art without departing from the scope of the present invention.

1. A method to optimize electrical energy production from a bifacial module (“BFM”) comprising a plurality of electrically interconnected bifacial photovoltaic cells, comprising:
providing a BFM comprising an edge seal;
providing a reflector assembly;
positioning said BFM at least about 0.15 meters above said reflector assembly;
adjusting an orientation of said BFM using a Tilt Correction Factor;
further adjusting said orientation using an Azimuth Correction Factor.

2. The method of claim 1, wherein said reflector assembly comprises an albedo of at least 0.7.

3. The method of claim 1, wherein said reflector assembly comprises an albedo of at least 0.9.

4. The method of claim 1, wherein said BFM comprises an average backside-to-frontside power ratio in the range of 0.8 to 1.

5. The method of claim 1, wherein said providing a BFM further comprises providing a BFM that does not comprise an integral backsheet.

6. The method of claim 1, wherein said providing a BFM further comprises providing a BFM that does not comprise a frame.

7. The method of claim 1, wherein said providing a BFM further comprises providing a BFM comprising:
a glass top member comprising a first periphery;
a glass bottom member comprising a second periphery;
an encapsulant disposed between said top member and said bottom member;
wherein:
said edge seal is continuously disposed between said glass top member and said glass bottom member and along said first periphery and said second periphery;
said plurality of electrically interconnected bifacial photovoltaic cells is disposed within said encapsulant.

8. The method of claim 7, further comprising providing an edge seal comprising desiccating particles disposed therein.

9. The method of claim 8, wherein said providing an edge seal comprising desiccating particles further comprises providing an edge seal comprising desiccating particles at between about 0.01 weight percent to about 10 weight percent.

10. The method of claim 7, wherein said providing a BFM further comprises providing a BFM that does not comprise a Jbox disposed directly above, or directly below, any of the plurality of electrically-interconnected bifacial photovoltaic cells.

11. The method of claim 10, further comprising:
providing a BFM module racking/support structure;
positioning said BFM module/support system over said reflector assembly;
disposing said BFM onto said module/support system such that none of the plurality of electrically-interconnected bifacial photovoltaic cells are shadowed by said BFM module raking/support structure.

12. The method of claim 11, wherein said BFM module/support system can accommodate more than one row of BFM modules, said method further comprising setting a minimum row spacing of about 0.5 meters.

13. A Bifacial Module, comprising:
a plurality of electrically-interconnected bifacial photovoltaic cells;
an edge seal;
wherein said BFM comprises an average backside-to-frontside power ratio in the range of 0.8 to 1.

14. The Bifacial Module of claim 13, wherein said BFM that does not comprise an integral backsheet.

15. The Bifacial Module of claim 13, wherein said BFM does not comprise a frame.

16. The Bifacial Module of claim 13, comprising:
a glass top member comprising a first periphery;
a glass bottom member comprising a second periphery;
an encapsulant disposed between said top member and said bottom member;
wherein:
said edge seal is continuously disposed between said glass top member and said glass bottom member and along said first periphery and said second periphery;
said plurality of electrically interconnected bifacial photovoltaic cells is disposed within said encapsulant.

17. The Bifacial Module of claim 16, wherein said edge seal comprises desiccating particles disposed therein.

18. The Bifacial Module of claim 17, wherein said providing an edge seal comprising desiccating particles further comprises providing an edge seal comprising desiccating particles at between about 0.01 weight percent to about 10 weight percent.

19. The Bifacial Module of claim 13, wherein said BFM does not comprise a Jbox disposed directly above, or directly below, any of the plurality of electrically-interconnected bifacial photovoltaic cells.

20. The Bifacial Module of claim 14, further comprising:
a racking/support structure;
wherein said BFM is disposed onto said module/support system such that none of the plurality of electrically-interconnected bifacial photovoltaic cells are shadowed by said raking/support structure.

21. The Bifacial Module of claim 15, wherein:
said support structure can accommodate more than one row of BFM modules;
said BFM module/support system is configured to have a minimum row spacing of about 0.5 meters.
